(19) United States
(12) Patent Application Publication
(10) Pub. No.: US 2025/0145859 A1
(43) Pub. Date: May 8, 2025

(54) SLURRY COMPOSITION FOR CHEMICAL MECHANICAL POLISHING

(71) Applicant: KCTECH CO., LTD., Gyeonggi-do (KR)

(72) Inventors: Ji Hye KIM, Gyeonggi-do (KR); Jae Ik LEE, Gyeonggi-do (KR); Dam Bi KIM, Gyeonggi-do (KR); Bo Hyeok CHOI, Gyeonggi-do (KR)

(73) Assignee: KCTECH CO., LTD., Gyeonggi-do (KR)

(21) Appl. No.: 18/938,313

(22) Filed: Nov. 6, 2024

(30) Foreign Application Priority Data
Nov. 6, 2023 (KR) 10-2023-0151856

(51) Int. Cl. C09G 1/02; C09K 3/14

(52) U.S. Cl. CPC C09G 1/02; C09K 3/1409

(57) ABSTRACT

A slurry composition for chemical mechanical polishing (CMP) is provided. The slurry composition includes colloidal silica particles, at least one nonionic compound among dextran, dextrose, and dextrin, an amino acid, a pH buffer, and a pH adjuster. The slurry composition may have a pH of 1 to 4.

### CROSS-REFERENCE TO RELATED APPLICATION

This application claims the benefit of Korean Patent Application No. 10-2023-0151856, filed on Nov. 6, 2023, in the Korean Intellectual Property Office, the entire disclosure of which is incorporated herein by reference for all purposes.

### BACKGROUND

### 1. Field

One or more embodiments relate to a slurry composition for chemical mechanical polishing (CMP).

### 2. Description of Related Art

With diversification and high integration of semiconductor devices, finer pattern forming techniques are being used, and the surface structure of the semiconductor devices is becoming more complex and a step difference between surface films is also widening accordingly. A chemical mechanical polishing (CMP) process is used as a planarization technology to remove a stepped portion of a specific film formed on a substrate in manufacturing of semiconductor devices.

The CMP process is a wide-area planarization technology that chemically reacts and mechanically removes the uneven surface of the wafer by supplying slurry to the contact area between the surface of the wafer to be processed and the polishing pad while moving the wafer and the polishing pad relatively, and planarizing the surface. In the CMP process, the polishing speed, the degree of flatness of the polishing surface, and the degree of scratches are important, and these are determined by the CMP process conditions, the type of slurry, and the type of polishing pad. The CMP is a widespread planarization technology to planarize a surface of a wafer that is in contact with a polishing pad by supplying a slurry to a contact area between the wafer and the polishing pad, and by mechanically removing an uneven surface of the wafer while relatively moving the wafer and the polishing pad through a chemical reaction. In the CMP process, a polishing speed, a planarization degree of a polished surface and incidence of scratches are important, which are determined based on, for example, CMP conditions, types of slurries, or types of polishing pads.

Recently, as the demand for faster and better electronic equipment such as smartphones or artificial intelligence devices increases, the demand for semiconductors and electronic components that are integrated in increasingly fine patterns and have superior durability is also increasing. Thus, a demand for slurry compositions for polishing a wafer to reduce fine scratches and obtain an excellent surface quality is also increasing in the CMP field.

### SUMMARY

To solve an issue of scratches on a surface of a wafer film due to mechanical polishing of abrasive particles, one or more embodiments provide a slurry composition for chemical mechanical polishing (CMP) that may significantly reduce scratch defects on a surface of a wafer and may secure an excellent storage stability instead of having an influence on a polishing rate.

However, goals to be achieved by the present disclosure are not limited to those described above, and other goals not mentioned above can be clearly understood by one of ordinary skill in the art from the following description.

According to an aspect, there is provided a slurry composition for CMP including colloidal silica particles, at least one nonionic compound among dextran, dextrose, and dextrin, an amino acid, a pH buffer, and a pH adjuster. The slurry composition may have a pH of 1 to 4.

The nonionic compound may be included in an amount of 0.001% by weight (wt %) to 0.1 wt % in the slurry composition.

The colloidal silica particles may be included in an amount of 0.01 wt % to 10 wt % in the slurry composition.

The colloidal silica particles may have a particle size of 10 nanometers (nm) to 200 nm.

The amino acid may be included in an amount of 0.01 wt % to 5.0 wt % in the slurry composition.

The amino acid may include at least one of arginine, lysine, histidine, aspartic acid, glutamic acid, asparagine, glutamine, tyrosine, serine, cysteine, threonine, glycine, alanine, (3-alanine, proline, tryptophan, methionine, phenylalanine, valine, leucine, and isoleucine.

The pH buffer may be included in an amount of 0.01 wt % to 2.0 wt % in the slurry composition.

The pH buffer may include at least one of an organic acid and an amine-based compound. The organic acid may include at least one of oxalic acid, malic acid, maleic acid, malonic acid, formic acid, lactic acid, acetic acid, picolinic acid, citric acid, succinic acid, tartaric acid, glutaric acid, glutamic acid, glycolic acid, propionic acid, fumaric acid, salicylic acid, pimelic acid, benzoic acid, butyric acid, aspartic acid, sulfonic acid, and phthalic acid. The amine-based compound may include at least one of benzylamine, monoethanolamine, diethanolamine, triethanolamine, trimethanolamine, dimethylbenzylamine, ethoxybenzylamine, monoisopropanolamine, aminoethylethanolamine, N,N-diethylethanolamine, diethylenetriamine (DETA), triethylenetetramine (TETA), tetraethylenepentamine (TEPA), pentaethylenehexamine (PEHA), bis(hexamethylene)triamine, N-(3-aminopropyl)ethylenediamine (Am3), N,N′-bis(3-aminopropyl)ethylenediamine (Am4), N,N,N′-tris(3-aminopropyl)ethylenediamine (Am5), N-3-aminopropyl-1,3-diaminopropane, N,N′-bis(3-aminopropyl)-1,3-diaminopropane, N,N,N′-tris(3-aminopropyl)-1,3-diaminopropane, bis-(3-aminopropyl)amine, dipropylenetriamine, and tripropylenetetramine.

The pH adjuster may include at least one of: at least one acidic material among hydrochloric acid, phosphoric acid, nitric acid, sulfuric acid, hydrofluoric acid, bromic acid, iodic acid, formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, aspartic acid, tartaric acid, and salts thereof; and at least one basic material among ammonia, ammonium methyl propanol (AMP), tetramethylammonium hydroxide (TMAH), ammonium hydroxide, potassium hydroxide, sodium hydroxide, magnesium hydroxide, rubidium hydroxide, cesium hydroxide, sodium bicarbonate, sodium carbonate, and imidazole.

A target film to be polished using the slurry composition may be a silicon oxide film, and a polishing rate for the silicon oxide film may be in a range of 200 angstroms per minute (Å/min) to 700 Å/min.

According to embodiments, a slurry composition for CMP that may significantly reduce scratch defects on a surface of a wafer may be provided. A nonionic compound of the slurry composition may function as a cushion for abrasive particles, and thus the slurry composition may reduce scratch defects on a surface of an oxide film and have an excellent storage stability instead of having an influence on a polishing rate.

It should be understood that the effects of the present disclosure are not limited to the effects described above, but include all effects that can be inferred from the configuration of the disclosure described in the detailed description or claims of the present disclosure.

### BRIEF DESCRIPTION OF THE DRAWING

These and/or other aspects, features, and advantages of the invention will become apparent and more readily appreciated from the following description of embodiments, taken in conjunction with the accompanying drawing of which:

FIG. 1 illustrates wafer surface defects in examples and comparative examples.

### DETAILED DESCRIPTION

Hereinafter, embodiments will be described in detail with reference to the accompanying drawing. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not intended to be limiting. The singular forms “a,” “an,” and “the” are intended to include the plural forms as well, unless the context clearly indicates otherwise. It will be further understood that the terms “comprises/comprising” and/or “includes/including” when used herein, specify the presence of stated features, integers, steps, operations, elements, components, and/or groups thereof but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In addition, when describing the embodiments with reference to the accompanying drawing, like reference numerals refer to like components and a repeated description related thereto will be omitted. In the description of embodiments, detailed description of well-known related structures or functions will be omitted when it is deemed that such description will cause ambiguous interpretation of the present disclosure.

Furthermore, the terms first, second, A, B, (a), and (b) may be used to describe components of the embodiments. These terms are used only for the purpose of discriminating one component from another component, and the nature, the sequences, or the orders of the components are not limited by the terms.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

It will be understood throughout the whole specification that, when one part “includes” or “comprises” one component, the part does not exclude other components but may further include the other components.

One or more embodiments relate to a slurry composition for chemical mechanical polishing (CMP). The slurry composition may include colloidal silica particles, at least one nonionic compound among dextran, dextrose, and dextrin, an amino acid, a pH buffer, and a pH adjuster. The slurry composition may have a pH of 1 to 4.

Dextran, which is a nonionic compound, is a viscous polysaccharide predominantly having (1→6)-α-glycosidic bonds of D-glucose. The slurry composition according to an embodiment may include dextran as a nonionic compound. The dextran may have a molecular weight of 30,000 to 160,000 and may include, for example, dextran 40, dextran 70, dextran 150, or a combination thereof.

Dextrose, which is a nonionic compound, may be a monosaccharide belonging to a D-isomer of glucose.

Dextrin may be a nonionic polymeric compound of D-glucose units linked by α-(1→4) or α-(1→6) glycosidic bonds and may be generated by a hydrolysis of starch and glycogen.

Since the slurry composition includes the nonionic compound, the nonionic compound may function as a cushion for abrasive particles, to reduce scratches on a surface of a wafer. In particular, dextran, dextrose, or dextrin may be used as a nonionic compound, and thus it is possible to reduce surface defects including scratches and secure an excellent storage stability instead of having an influence on the polishing rate.

According to an embodiment, the nonionic compound may be included in an amount of 0.001% by weight (wt %) to 0.1 wt % in the slurry composition, desirably in an amount of 0.005 wt % to 0.1 wt %, and more desirably in an amount of 0.01 wt % to 0.05 wt %. If the amount of the nonionic compound exceeds the upper limit, the nonionic compound that is excessively added may remain on a surface of a wafer film, which may lead to organic defects. If the amount of the nonionic compound falls below the lower limit, the nonionic compound may fail to sufficiently function as a cushion for abrasive particles, which may result in a decrease in performance of preventing defects from occurring on the surface of the wafer film.

According to an embodiment, the colloidal silica particles may be included in an amount of 0.01 wt % to 10 wt % in the slurry composition, and desirably in an amount of 0.1 to 5 wt %. If the amount of the colloidal silica particles exceeds the upper limit, a possibility of causing particulate scratches may increase, and if the amount of the colloidal silica particles falls below the lower limit, a polishing speed may decrease due to an insufficient polishing effect.

According to an embodiment, the colloidal silica particles may have a particle size of 10 nanometers (nm) to 200 nm, desirably have a particle size of 20 nm to 150 nm, and more desirably have a particle size of 30 nm to 100 nm. A particle diameter of the colloidal silica particles may be an average particle diameter of a plurality of particles within a view field range that may be measured by X-ray diffraction (XRD), scanning electron microscope (SEM) analysis, transmission electron microscope (TEM) analysis, Brunauer-Emmett-Teller (BET) analysis, or dynamic light scattering (DLS). If the size of the colloidal silica particles exceeds the upper limit, excessive polishing may be performed, which may result in dishing, erosion, and surface defects. If the size of the colloidal silica particles falls below the lower limit, the polishing rate may decrease, or relatively small particles may be generated due to milling, which may lead to a decrease in cleanability and an excess of defects on the surface of the wafer.

According to an embodiment, the amino acid may be included in an amount of 0.01 wt % to 5.0 wt % in the slurry composition, desirably in an amount of 0.1 wt % to 4.0 wt %, and more desirably in an amount of 1.0 wt % to 3.0 wt %. If the amount of the amino acid exceeds the upper limit, a dispersion stability may decrease, and if the amount of the amino acid falls below the lower limit, it may be impossible to secure a sufficient polishing rate for the slurry composition.

According to an embodiment, the amino acid may include at least one of arginine, lysine, histidine, aspartic acid, glutamic acid, asparagine, glutamine, tyrosine, serine, cysteine, threonine, glycine, alanine, β-alanine, proline, tryptophan, methionine, phenylalanine, valine, leucine, and isoleucine. A single type of amino acids may be used, or at least two types of amino acids may be mixed and used.

According to an embodiment, the pH buffer may be included in an amount of 0.01 wt % to 2.0 wt % in the slurry composition, and desirably in an amount of 0.05 wt % to 1.0 wt %. If the amount of the pH buffer exceeds the upper limit, the storage stability and polishing rate may decrease. If the amount of the pH buffer falls below the lower limit, physical properties of the slurry composition may change over time due to a decrease in a pH stability.

According to an embodiment, the pH buffer may include at least one of an organic acid and an amine-based compound. The organic acid may include at least one of oxalic acid, malic acid, maleic acid, malonic acid, formic acid, lactic acid, acetic acid, picolinic acid, citric acid, succinic acid, tartaric acid, glutaric acid, glutamic acid, glycolic acid, propionic acid, fumaric acid, salicylic acid, pimelic acid, benzoic acid, butyric acid, aspartic acid, sulfonic acid, and phthalic acid. The amine-based compound may include at least one of benzylamine, monoethanolamine, diethanolamine, triethanolamine, trimethanolamine, dimethylbenzylamine, ethoxybenzylamine, monoisopropanolamine, aminoethylethanolamine, N,N-diethylethanolamine, diethylenetriamine (DETA), triethylenetetramine (TETA), tetraethylenepentamine (TEPA), pentaethylenehexamine (PEHA), bis(hexamethylene)triamine, N-(3-aminopropyl)ethylenediamine (Am3), N,N′-bis(3-aminopropyl)ethylenediamine (Am4), N,N,N′-tris(3-aminopropyl)ethylenediamine (Am5), N-3-aminopropyl-1,3-diaminopropane, N,N′-bis(3-aminopropyl)-1,3-diaminopropane, N,N,N′-tris(3-aminopropyl)-1,3-diaminopropane, bis-(3-aminopropyl)amine, dipropylenetriamine, and tripropylenetetramine. Organic acids or amine-based compounds may be used as pH buffers regardless of the type of organic acids or amine-based compounds, and at least two types of organic acids or amine-based compounds may be mixed and used.

In an embodiment, the pH adjuster may include at least one of: at least one acidic material among hydrochloric acid, phosphoric acid, nitric acid, sulfuric acid, hydrofluoric acid, bromic acid, iodic acid, formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, aspartic acid, tartaric acid, and salts thereof; and at least one basic material among ammonia, ammonium methyl propanol (AMP), tetramethylammonium hydroxide (TMAH), ammonium hydroxide, potassium hydroxide, sodium hydroxide, magnesium hydroxide, rubidium hydroxide, cesium hydroxide, sodium bicarbonate, sodium carbonate, and imidazole.

The pH of the slurry composition may be in a range of 1 to 4. If the pH of the slurry composition exceeds the upper limit, zeta potentials on the surface of the wafer may increase and an oxide film may be negatively charged, which may result in a decrease in the polishing rate. Thus, to realize the above pH range, the pH adjuster may be properly used.

A target film to be polished using the slurry composition may be a silicon oxide film. A polishing rate for the silicon oxide film may be in a range of 200 angstroms per minute (Å/min) to 700 Å/min, and desirably in a range of 300 Å/min to 600 Å/min.

Hereinafter, the present disclosure will be described in greater detail through examples. However, the examples are intended to describe the present disclosure and the scope of the present disclosure is not limited thereto.

### EXAMPLES

### 1. Preparation Example: Preparation of Slurry Composition for CMP

2.0 wt % of colloidal silica particles with a size of 70 nm as abrasive particles, 0.1 wt % of picolinic acid as a pH buffer, 2.0 wt % of glycine as a polishing rate enhancer, and a nonionic compound shown in Table 1 below were added, a pH adjuster was properly added, and pH was adjusted based on Table 1, to prepare slurry compositions for CMP of examples and comparative examples.

TABLE 1

| | Nonionic compound | Amount of nonionic compound | pH |
|---|---|---|---|
| Example 1 | Dextran 40 | 0.001 | 2 |
| Example 2 | Dextran 40 | 0.005 | 2 |
| Example 3 | Dextran 40 | 0.01 | 2 |
| Example 4 | Dextran 40 | 0.05 | 2 |
| Example 5 | Dextran 40 | 0.1 | 2 |
| Example 6 | Dextran 70 | 0.01 | 2 |
| Example 7 | Dextrose | 0.005 | 2 |
| Example 8 | Dextrose | 0.05 | 2 |
| Example 9 | Dextrin | 0.005 | 2 |
| Example 10 | Dextrin | 0.05 | 2 |
| Comparative | Dextran 40 | 0.5 | 2 |
| Example 1 | | | |
| Comparative | Dextran 70 | 0.5 | 2 |
| Example 2 | | | |
| Comparative | — | — | 2 |
| Example 3 | | | |
| Comparative | — | — | 11 |
| Example 4 | | | |
| Comparative | Hydroxyethyl | 0.005 | 2 |
| Example 5 | cellulose (HEC) | | |
| Comparative | Polyethylene | 0.005 | 2 |
| Example 6 | glycol (PEG) | | |
| Comparative | Polyethylene | 0.05 | 2 |
| Example 7 | glycol (PEG) | | |
| Comparative | Dextran | 0.005 | 11 |
| Example 8 | | | |

### 2. Experimental Example: Evaluation of Surface Defects and Polishing Rate

A silicon oxide film was polished under evaluation conditions shown in Table 2 below, using the slurry compositions of Examples 1 to 10 and Comparative Examples 1 to 8, and a polishing rate, surface defects, and a storage stability were evaluated. The storage stability was evaluated by measuring a particle size and visually determining a layer separation after the slurry compositions were stored at a temperature of 60° C. for seven days after a preparation of the slurry compositions. Samples in which layer separation over time or an increase in the size of abrasive particles were observed were determined to have poor storage stability and were marked as “X.” On the contrary, samples in which layer separation or an increase in the size of abrasive particles did not occur were determined to have excellent storage stability and were marked as “◯.”

TABLE 2

| Evaluation equipment | SP-01/K1000 (manufactured by KCTech) |
|---|---|
| Carrier rpm | 78 |
| Platen rpm | 83 |
| Wafer pressure | 2.0 |
| R-Ring pressure | 3.7 |
| Slurry flow rate | 200 ml/min |
| Polishing pad | IC 1000 |

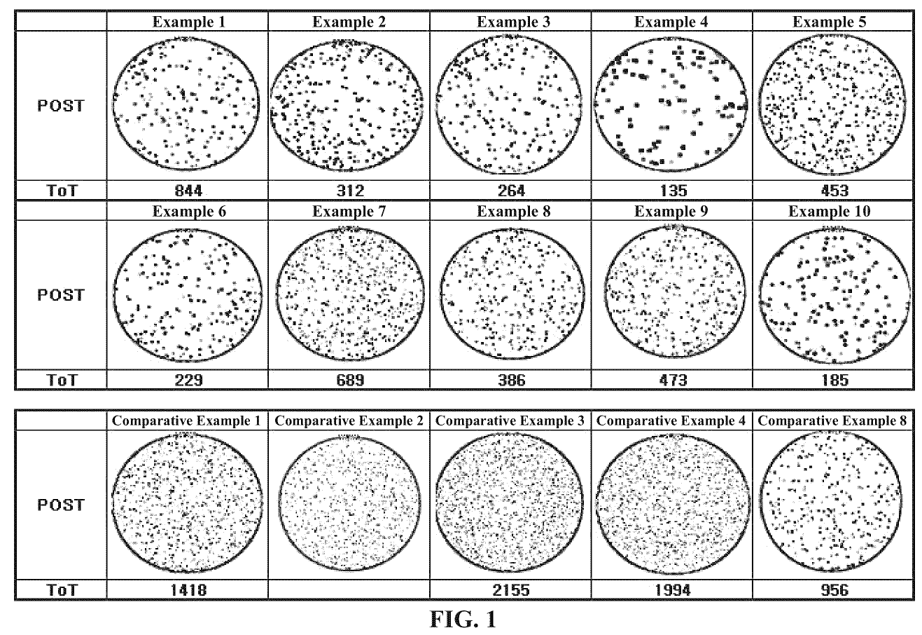

A polishing rate for the silicon oxide film, the number of defects of the silicon oxide film, and the storage stability of the slurry compositions are shown in Table 3 below, and FIG. 1 illustrates a distribution of defects appeared on a surface of a wafer after a CMP process.

TABLE 3

| | Polishing rate (Å/min) | Number of | Storage |
|---|---|---|---|
| | for oxide film | defects (EA) | stability |
| Example 1 | 412 | 844 | ◯ |
| Example 2 | 415 | 312 | ◯ |
| Example 3 | 411 | 264 | ◯ |
| Example 4 | 413 | 135 | ◯ |
| Example 5 | 411 | 453 | ◯ |
| Example 6 | 405 | 229 | ◯ |
| Example 7 | 420 | 689 | ◯ |
| Example 8 | 418 | 386 | ◯ |
| Example 9 | 417 | 473 | ◯ |
| Example 10 | 415 | 185 | ◯ |
| Comparative Example 1 | 380 | 1418 | Δ |
| Comparative Example 2 | 354 | 1574 | Δ |
| Comparative Example 3 | 414 | 2155 | ◯ |
| Comparative Example 4 | 10 | 1994 | ◯ |
| Comparative Example 5 | 415 | — | X |
| Comparative Example 6 | 411 | — | X |
| Comparative Example 7 | 410 | — | X |
| Comparative Example 8 | 12 | 956 | ◯ |

(For Comparative Examples 5 to 7, defects were not evaluated due to a layer separation phenomenon)

Referring to Table 3, it can be confirmed that the slurry compositions of Examples 1 to 10 and Comparative Example 8 in which dextran, dextrose, and dextrin were used as nonionic compounds have an excellent storage stability in comparison to Comparative Examples 5 to 7 in which hydroxyethyl cellulose (HEC) and polyethylene glycol (PEG) were used as nonionic compounds and that in Examples 1 to 10 in which dextran, dextrose, and dextrin were used as nonionic compounds, the number of defects was remarkably less than in Comparative Examples 3 and 4 in which a nonionic polymer was not included. In addition, it can be found that it was possible to secure a predetermined polishing rate for an oxide film in Examples 1 to 10 and Comparative Examples 5 to 7 in which the pH was adjusted to 2, whereas it was impossible to achieve a sufficient polishing rate for the oxide film in Comparative Examples 4 and 8 in which the pH was adjusted to 11. It can be confirmed that in Comparative Examples 1 and 2 in which an excess, i.e., 0.5 wt %, of dextran was added, the polishing rate for the oxide film was reduced and the number of defects was increased.

Therefore, in the present disclosure, dextran, dextrose, and dextrin as nonionic compounds may be included in an appropriate weight range, and an acidic pH may be maintained, to provide a slurry composition for CMP that may reduce surface defects of a wafer while securing a predetermined polishing rate and that has an excellent storage stability.

While the embodiments are described with reference to the drawing, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A slurry composition for chemical mechanical polishing (CMP), the slurry composition comprising:
colloidal silica particles;
at least one nonionic compound selected from a group consisting of dextran, dextrose, and dextrin;
an amino acid;
a pH buffer; and
a pH adjuster,
wherein the slurry composition has a pH of 1 to 4.

2. The slurry composition of claim 1, wherein the nonionic compound is included in an amount of 0.001% by weight (wt %) to 0.1 wt % in the slurry composition.

3. The slurry composition of claim 1, wherein the colloidal silica particles are included in an amount of 0.01 wt % to 10 wt % in the slurry composition.

4. The slurry composition of claim 1, wherein the colloidal silica particles have a particle size of 10 nanometers (nm) to 200 nm.

5. The slurry composition of claim 1, wherein the amino acid is included in an amount of 0.01 wt % to 5.0 wt % in the slurry composition.

6. The slurry composition of claim 1, wherein the amino acid comprises at least one selected from a group consisting of arginine, lysine, histidine, aspartic acid, glutamic acid, asparagine, glutamine, tyrosine, serine, cysteine, threonine, glycine, alanine, β-alanine, proline, tryptophan, methionine, phenylalanine, valine, leucine, and isoleucine.

7. The slurry composition of claim 1, wherein the pH buffer is included in an amount of 0.01 wt % to 2.0 wt % in the slurry composition.

8. The slurry composition of claim 1, wherein
the pH buffer comprises at least one selected from a group consisting of an organic acid and an amine-based compound,
the organic acid comprises at least one selected from a group consisting of oxalic acid, malic acid, maleic acid, malonic acid, formic acid, lactic acid, acetic acid, picolinic acid, citric acid, succinic acid, tartaric acid, glutaric acid, glutamic acid, glycolic acid, propionic acid, fumaric acid, salicylic acid, pimelic acid, benzoic acid, butyric acid, aspartic acid, sulfonic acid, and phthalic acid, and
the amine-based compound comprises at least one selected from a group consisting of benzylamine, monoethanolamine, diethanolamine, triethanolamine, trimethanolamine, dimethylbenzylamine, ethoxybenzylamine, monoisopropanolamine, aminoethylethanolamine, N,N-diethylethanolamine, diethylenetriamine (DETA), triethylenetetramine (TETA), tetraethylenepentamine (TEPA), pentaethylenehexamine (PEHA), bis(hexamethylene)triamine, N-(3-aminopropyl)ethylenediamine (Am3), N,N′-bis(3-aminopropyl)ethylenediamine (Am4), N,N,N′-tris(3-aminopropyl)ethylenediamine (Am5), N-3-aminopropyl-1,3-diaminopropane, N,N′-bis(3-aminopropyl)-1,3-diaminopropane, N,N,N′-tris(3-aminopropyl)-1,3-diaminopropane, bis-(3-aminopropyl)amine, dipropylenetriamine, and tripropylenetetramine.

9. The slurry composition of claim 1, wherein the pH adjuster comprises at least one selected from a group consisting of:
at least one acidic material selected from a group consisting of hydrochloric acid, phosphoric acid, nitric acid, sulfuric acid, hydrofluoric acid, bromic acid, iodic acid, formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, aspartic acid, tartaric acid, and salts thereof; and
at least one basic material selected from a group consisting of ammonia, ammonium methyl propanol (AMP), tetramethylammonium hydroxide (TMAH), ammonium hydroxide, potassium hydroxide, sodium hydroxide, magnesium hydroxide, rubidium hydroxide, cesium hydroxide, sodium bicarbonate, sodium carbonate, and imidazole.

10. The slurry composition of claim 1, wherein
a target film to be polished using the slurry composition is a silicon oxide film, and
a polishing rate for the silicon oxide film is in a range of 200 angstroms per minute (Å/min) to 700 Å/min.
